(19) United States
(12) Patent Application Publication
(10) Pub. No.: US 2019/0195928 A1
(43) Pub. Date: Jun. 27, 2019

(54) DEVICE FOR MAKING EMC TEST MEASUREMENTS

(71) Applicant: Anita Silvia ZWERGER-SCHUSTER, Munchen (DE)

(72) Inventor: Anita Silvia ZWERGER-SCHUSTER, Munchen (DE)

(21) Appl. No.: 16/289,855

(22) Filed: Mar. 1, 2019

Related U.S. Application Data
(63) Continuation of application No. PCT/EP2017/072019, filed on Sep. 1, 2017.

(30) Foreign Application Priority Data
Sep. 1, 2016 (DE) 20 2016 104 835.4

(51) Int. Cl. G01R 29/10; G01J 5/00; G01J 5/08; G01R 29/08

(52) U.S. Cl. CPC G01R 29/105; G01J 5/0096; G01J 5/0859; G01J 2005/0077; G01R 29/0835; G01R 29/0878; G01R 29/0892

(57) ABSTRACT

A device for making EMC test measurement is provided, the device comprising a measurement cell configured as a mobile box. The box comprises an opening at one side, which may be opened and closed again at least partially, where the opening is configured such that a system to be inspected can be introduced into the interior of the box through it. The interior of the box is subdivided into two areas, a measurement device can be arranged in either one of the areas, and the system to be inspected can be arranged in the other area. The subdivision of the interior of the box into two areas results from a plate, wherein the plate comprises an absorber layer, a damping layer, or a shielding layer, in order to prevent disturbances of the system to be inspected by the measurement devices.

### CROSS REFERENCE TO RELATED APPLICATIONS

This application is a continuation of International Application No. PCT/EP2017/072019, filed on Sep. 1, 2017, which takes priority from German Application No. 10 2016 104 835.4, filed on Sep. 1, 2016, the contents of each of which are incorporated by reference herein.

### TECHNICAL FIELD

The invention relates to a device for making EMC test measurements, by means of which the electromagnetic compatibility of a technical device may be inspected or checked. In the following, the technical device, the compatibility of which is to be inspected, is referred to as the “system to be inspected.”

### BACKGROUND

Nowadays, EMC test measurements usually are performed in a specific stationary EMC laboratory. Here, the measurement devices are arranged outside of the EMC laboratory fixedly. The experimental arrangements, hereby, mostly are very complex, because the system to be inspected, at first, has to be transported into the EMC laboratory, and the measurement devices have to be arranged correctly manually within the EMC laboratory, requiring substantial expenditure of time and additional costs.

Further, it is known to arrange the system to be inspected within some kind of measurement cell, in order to reduce the ambient influences on the measurement. The measurement devices themselves are also located outside of the box, and, if required, have to be connected to the measurement cell. However, such systems are not suitable as mobile EMC laboratories, because the measurement cell and the measurement devices have to be transported separately. Also here, the system to be inspected and the measurement devices have to be arranged with respect to each other manually in a correct manner, requiring a substantial expenditure of time.

A measurement cell known from prior art is shown in FIG. 1(a). The measurement cell basically consists of an umbrella tent. The tent may be opened at its side. Also here, the measurement devices have to be fixed additionally outside of the measurement cell.

A further measurement cell known from the prior art is shown in FIG. 1(b). The shield is shown much better in the measurement cells shown in FIG. 1 (b) than in the measurement cells shown in FIG. 1 (a). However, also here, the measurement devices have to be attached outside of the measurement cell.

Moreover, the measurement cells known from the prior art have the disadvantage that only certain types of measurements can be carried out such that the full range of applications of an EMC laboratory cannot be reached at all.

### SUMMARY

Therefore, it is an object of the present invention to at least partially avoid the disadvantages known from the prior art, and to provide a device for making EMC test measurements, which, on the one hand, can be used as mobile EMC measurement system without the measurement devices having to be transported separately, and which allows for a substantially larger range of applications than conventional measurement cells. Further, the shielding should not be affected by this.

According to the invention, this object may be solved by a device for making EMC test measurements according to the independent claim. Preferred embodiments and further developments of the invention are defined in the dependent claims.

Accordingly, a device for making EMC test measurements is provided, wherein the device comprises a measurement cell configured as a mobile box, wherein
the box has an opening at one side, which can be opened at least partially and which can be closed again, wherein the opening is configured such that at least one system to be inspected can be brought into the interior of the box through it,
the interior of the box is divided into two areas, preferably, into an upper area and a lower area,
the measurement devices can be arranged in either one of the two areas (device area), and the system to be inspected can be arranged in the respectively other area (measurement area), and
the subdivision of the interior of the box into two areas results from a plate, wherein the plate comprises an absorber layer and/or a damping layer and/or a shielding layer, in order to prevent disturbances of the system to be inspected by the measurement devices and/or disturbances of the system to be inspected by the system to be inspected itself to a great extent.

The plate may consist of one or more partial plates. The plate and the partial plates, respectively, may be ferrite plates. Alternatively, the plates and the partial plates, respectively, may comprise a metal plate, preferably made from aluminum, onto which a Mu-metal foil is applied, and on which the ferrite plates are fixed.

Thereby, the system to be inspected as well as the measurement devices may be arranged within the box. The box including the measurement devices may be transported easily. The plate with the absorber layer and/or damping layer and/or shielding layer ensures that disturbances of the system to be inspected by the measurement devices and/or disturbances of the measurement devices by the system to be inspected itself are prevented to a large extent. Thereby, the measurement devices may also remain within the box during the measurement such that an arrangement of the measurement devices, as it is required according to the prior art, is not necessary.

The opening of the box, i.e., the opening of the measurement area may be closed by flaps or by doors.

It is advantageous, if, besides the plate subdividing the box into two areas, also the walls (sidewalls and ceiling or upper wall) of the measurement area comprise an absorber layer and/or a damping layer and/or a shielding layer.

Further, it is advantageous, if also the flaps or doors, by means of which the measurement area can be closed, comprise an absorber layer and/or a damping layer and/or a shielding layer.

Thereby, the entire measurement area can be shielded from the outside, and disturbances of the system to be inspected and undesired influences on the measurements can be prevented.

In the measurement area, at least one means selected from the group comprising a robot arm, a rotary plate, camera systems, an EMC thermal imaging camera, a thermal imaging camera, an EMC antenna, sensors, a microphone, illumination, an EMC fan, and combinations thereof may be arranged. In the following, these are commonly referred to as “components”.

The measurement devices may be arranged within the device area releasably, in order to allow for an easy and quick exchange of the measurement devices.

The components arranged within the measurement area may be arranged within the measurement area releasably, in order to allow for an easy and quick exchange of the components.

Thereby, a completely modular assembly of the EMC measurement device is achieved such that the EMC measurement device may be adapted to diverse experimental setups. In particular, during a transport of the EMC measurement device, the components as well as the measurement devices may remain within the EMC measurement device, thereby substantially facilitating the transport. Moreover, the components and the measurement devices, thus, are protected from damages during the transport.

It is preferable, if at least one display means, preferably, one or two flat screens, are arranged at the outer wall of the box, preferably at the left and/or right outer wall, which may be coupled to the components in the measurement area and/or to the measurement devices in the measurement area operatively. Hereby, the coupling is accomplished such that they do not influence the measurements, i.e., possibly required cables are guided to the outside of the absorber layer, the damping layer, and/or the shielding layer, or are shielded accordingly.

The display means may be arranged at the box releasably, and/or it may be arranged at the box pivotably.

The measurement devices may be selected from the group comprising at least an analyzer, and oscilloscope, a power supply unit, a T-network reproduction, a video recorder, and combinations thereof. Further different measurement devices are possible. Due to the modular structure of the device according to the invention, the measurement devices may be exchanged according to the needs and requirements with respect to the measurement to be performed.

Preferably, the robot arm is configured and arranged relative to the rotary plate such that at least one sensor or at least one measurement means may be moved by it relative to the rotary plate. Preferably, a sensor, as a near field sensor or a near field probe, may be advanced to the system to be inspected by means of the robot arm.

The robot arm may be controllable from outside of the box, for example, by means of a joystick, a mouse, or another input device.

The EMC antenna and the measurement area may be configured so as to be alignable, whereby the alignment of the EMC antennas is accomplished from the inside, preferably, however, from the outside of the box.

The camera system may comprise at least one, preferably two, especially preferred four cameras, wherein the cameras preferably are arranged stationary in the corner regions in the inside of the measurement area.

The camera system may also comprise at least one thermal image camera, wherein the thermal image camera is arranged movably relative to the rotary plate in the measurement area. For this, it may be preferable, if the thermal image camera is configured so as to be retractable and extendable.

The system to be inspected may be arranged at or on the rotary plate. The rotary plate may be controlled from outside of the box, in particular, its rotation direction and its rotational speed.

It is advantageous, if the rotary plate comprises ports for the system to be inspected. Thus, for example, data of the system to be inspected may be transmitted to the outside, or the system to be inspected may be controlled from the outside. Thus, with respect to a mobile telephone as a system to be inspected, for example, the transmission power of the mobile telephone may be set from the outside. For example, the ports used may be USB ports.

Since all components in the measurement area and, if needed, also the system to be inspected may be controlled from outside of the box, a fully automatic EMC inspection may be performed comprising several individual inspection steps, wherein in each inspection step, the arrangement of the sensors or measurement systems may be modified relative to the system to be inspected. For this, the box does not have to be opened. The control may be accomplished by means of a computer or a microcontroller, which also may be arranged within the device area. A complete EMC test as well as an error analysis, for example, by means of the cameras and/or the near field probe, may be carried out substantially faster.

The sidewalls of the box may consist of a metal, in particular, of aluminum, particularly preferred, of anodized aluminum.

According to an embodiment of the invention, the box may have a maximum dimension of 300×240×260, preferably of 240×140×160, particularly preferred of 140×60×80 (L×W×H in cm). Larger boxes, however, are also covered by the invention, as far as their weight including the measurement devices accommodated therein is suitable for mobile use.

### BRIEF DESCRIPTION OF THE DRAWINGS

Details and features, in particular, preferred embodiments and further developments of the invention can be derived from the subsequent description in connection with the drawing, in which:

FIGS. 1(a) and 1(b) show two examples of an EMC measurement cell according to the prior art;

FIGS. 2(a) and 2(b) show overviews of an EMC measurement device according to the invention;

FIG. 3 shows an EMC measurement device according to the invention in an opened state;

FIG. 4 shows an EMC measurement device according to the invention with an EMC antenna arranged therein (according to two different embodiments and positions);

FIG. 5 shows an EMC measurement device according to the invention with a robot arm arranged therein;

FIG. 6 shows an EMC measurement device according to the invention with a thermal image camera arranged therein; and

FIG. 7 shows an EMC measurement device according to the invention with a video camera arranged therein.

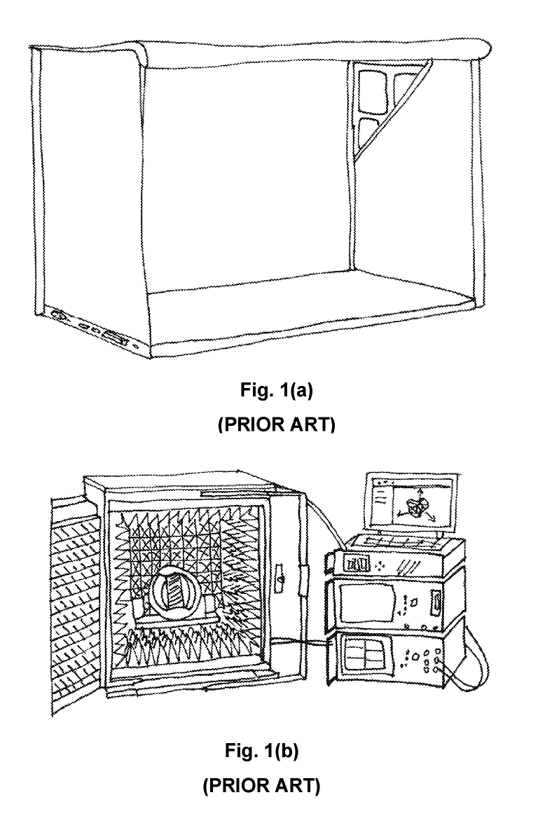

### DETAILED DESCRIPTION

With respect to the invention, a mobile device (in the following also referred to as measurement cell, EMC measurement cell, or box) is concerned, by means of which EMC measurements and/or error analyses may be carried out. The measurement devices necessary for the measurements are not located outside of the measurement cell, as is usual according to prior art, but rather are integrated in the measurement cell, which is designed as a box. The emitted interference (e.g., interference signals) of the measurement devices do not lead to a disturbance of the measurement, because an absorber and/or a shielding and/or a damping layer is arranged between the measurement area, in which the measurements are made, and the device area. The absorber and/or shielding and/or damping layer is part of a plate, which subdivides the interior of the box into the two areas, measurement area and device area.

Additionally, absorber and/or shielding and/or damping layers may be attached to the outer boards of the measurement area such that it is efficiently and sure it that interferences from the outside do not affect the measurements.

By means of the device according to the invention, all types of EMC test measurements may be made, starting from the development support, up to the production, as well as error analysis.

The device according to the invention has substantial advantages compared to systems known from prior art:
1. All components necessary for the measurements, as measurement devices, drive devices, and control devices, here, are integrated directly into the box and are not located separately and/or outside.
2. All components can be used immediately without additional effort. An additional effort for the attachment of the components is omitted.
3. During the transport, all components are not transported individually, but rather together, without reconstruction or dismantling measures. Moreover, the components are efficiently protected against transport damages.
4. Because all components are integrated into the box, a quick assembly and dismantling as well as a change of location of the entire measurement device is possible.
5. Without additional effort, all types of wire-bound measurements may be carried out.
6. All types of the “radiated emission” measurements (Radiated Emission measurements) may be carried out without additional effort.
7. For a wire-bound measurement, an immediate error analysis of the system to be inspected is possible.
8. Magnetic fields of the system to be inspected can be localized immediately (e.g., by means of a thermal image camera).

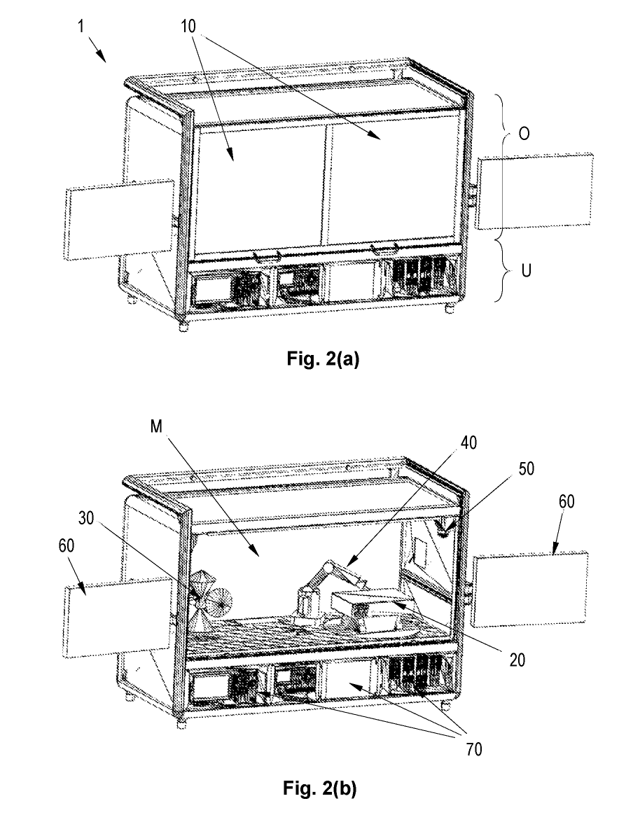

FIG. 2(a) shows a device according to the invention in a closed state.

Here, the box 1 consists of a metal box having a length of 140 cm, a width of 60 cm, and a height of 80 cm. Other dimensions are possible. A cover, which may be slid open, is provided at the longitudinal side. Instead of a slidable cover, also a pivotable cover or two pivotable doors/covers may be provided.

The box is divided into two areas or regions, as can be seen in FIG. 2(b), in which the device according to the invention is shown in an opened state. In the lower area U, which here has a length of 140 cm and a height of 20 cm, the measurement devices 70, the drives and to the control unit are located. In the upper area O, the actual measurement chamber (M) with a rotary plate 20, and antenna 30, a robot arm 40, cameras 50, illumination (not shown here) and a microphone (not shown here) are located. The cameras may comprise monitoring cameras and thermal image cameras 55.

The upper area O of the measurement cell and the lower area U of the measurement cell are subdivided by an absorber layer and/or a damping layer and/or a shielding such that the interferences of the devices do not affect the measurement results of the systems to be inspected. The absorber layer and/or the damping layer and/or the shielding may be formed by a metal plate, onto which a layer of ferrite tiles is applied having, for example, a thickness of 60 mm. Alternatively, a Mu-metal foil may be applied onto a metal plate, on which, in turn, the ferrite tiles are arranged. This absorber layer and/or damping layer and/or shielding may also be formed by several segments.

The walls (side walls and ceiling or upper wall) of the upper area O (measurement area) and the covers or doors 10 also comprise an absorber layer and/or damping layer and/or shielding layer such that the inner space of the upper area O is completely shielded against the outside, and disturbances of the system to be inspected may be prevented efficiently. For this, a shielding foil or a Mu-metal foil may be attached to the inner walls and to the ceiling as EMC foil, onto which an absorber layer may be applied. As absorber layer, a polyurethane foam may be used, which preferably covers a frequency range of approximately 30 MHz to 10 GHz. Alternatively, the walls may be shielded, similar to the upper area O of the measurement cell, from the lower area U of the measurement cell.

At the sides of the measurement cell, two mounts are attached for monitors 60, by means of which the measurements and the experimental setup may be displayed.

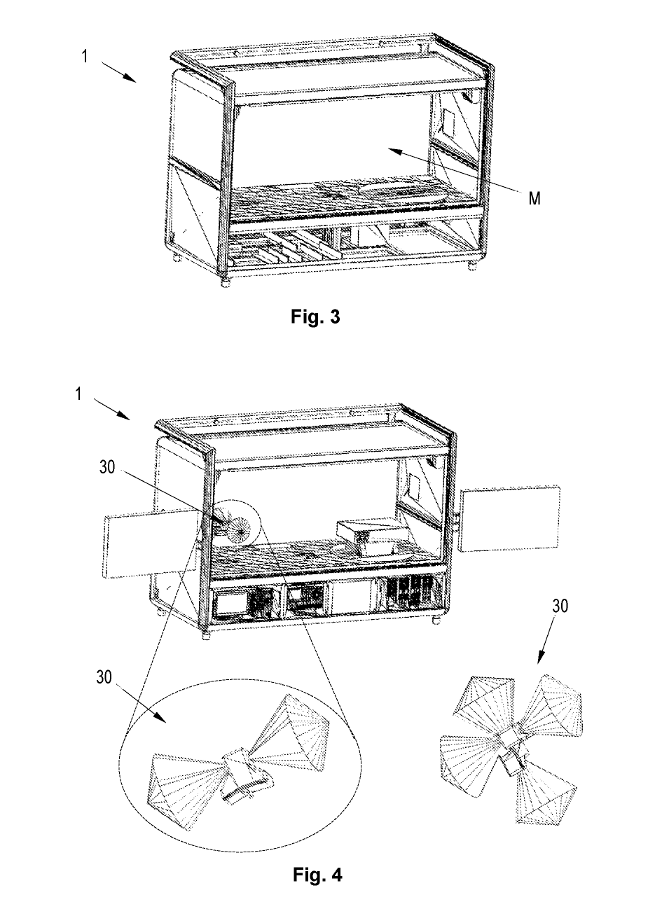

FIG. 3 shows a box 1 according to the invention in an opened state, in which no measurements devices have been arranged yet. Here, the slide-in units for the measurement devices 70 provided in the lower area U can be seen. The housing of the box, here, is made from an aluminum frame. The side parts and the doors 10, here, are made from a coated aluminum sheet.

FIG. 4 shows the device 1 according to the invention with the measurements devices 70 arranged in the lower area U and with the rotary plate 20 and an EMC antenna 30 arranged in the upper area O. The EMC antenna is shown in two different designs and in an enlarged view. The EMC antenna 30 may be configured movably.

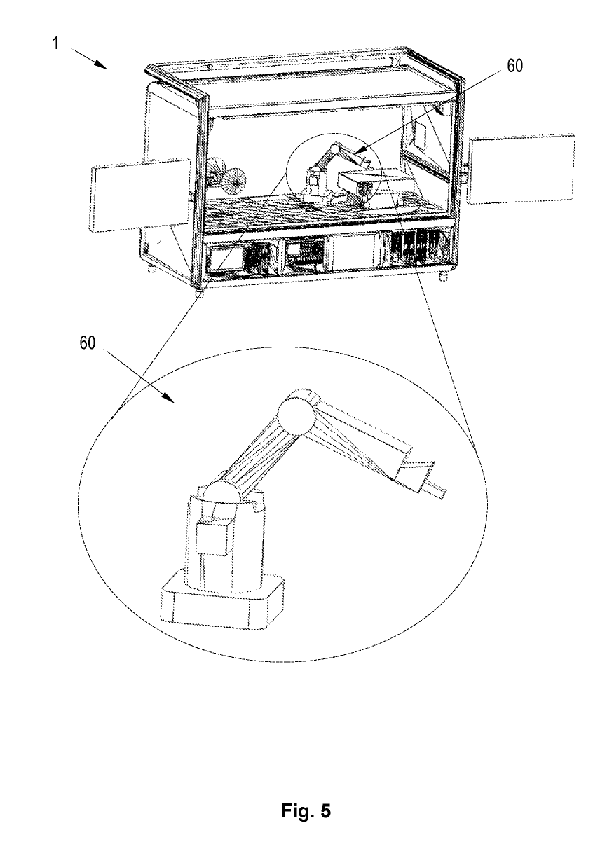

Additionally, according to FIG. 5, a robot arm 40 is arranged in the upper area O, which additionally is illustrated in an enlarged view.

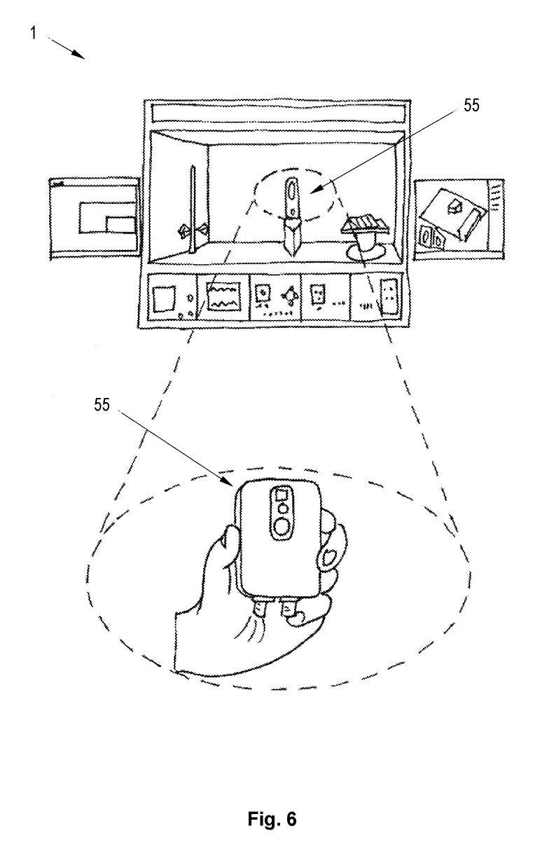

According to FIG. 6, a thermal image camera 55 is arranged in the upper area O. Additionally, also here, a robot arm 40 and/or further components may be arranged, which however, are not shown here.

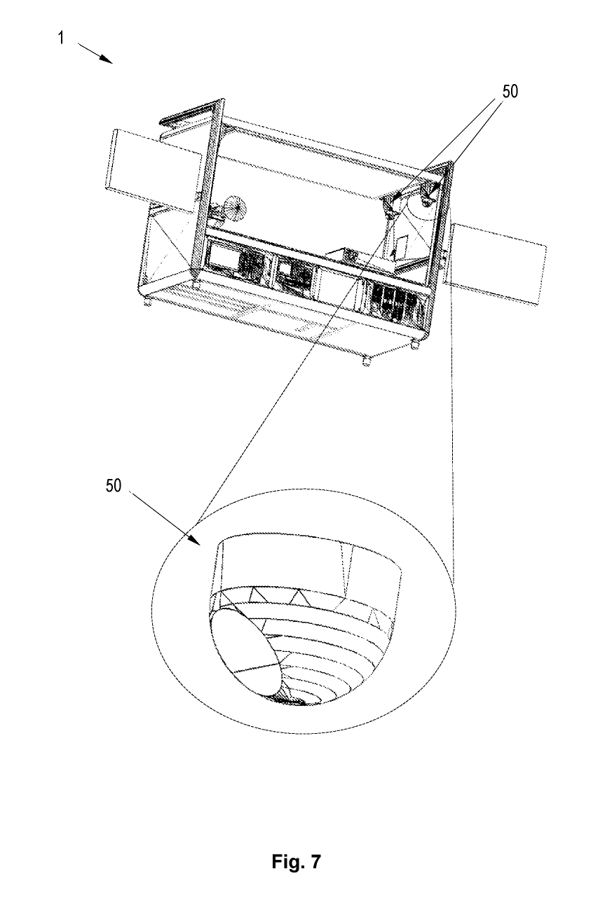

According to FIG. 7, there are arranged four cameras 50 (one in every corner), preferably, video cameras, wherein, here, only the two cameras 50 on right hand side can be seen. Additionally, also here, a robot arm and/or a thermal image camera and/or further components may also be arranged.

In the following, the individual components of the device 1 according to the invention are described in detail. According to the invention, in general, all components may be arranged in combination with each other.

### The Rotary Plate 20

The rotary plate 20 is configured in order to receive the system to be inspected. The rotary plate, here, has a diameter of approximately 50 cm, and is driven by a motor. Preferably, the rotary plate may rotate about 360° in both directions. The speed, acceleration, and duration of the rotation may be controlled automatically by means of a software program. At the rotary plate, preferably, in the middle of the rotary plate, various ports may be provided, as USB, LAN, AC, and/or DC ports for the connection of the system to be measured, whereby entangling of the ports is prevented. These terminals may be guided to the outside via sliding contacts and cable connections connected thereto. The cable connections, here, preferably are shielded with respect to EMC.

The rotary plate may be moved by means of a pneumatic drive or a motor (electro-motor) arranged outside of the measurement area, i.e., it may be rotated and it may be adjusted with respect to its height. For example, the electro-motor provided for the drive of the rotary plate may be arranged immediately below the rotary plate in the lower area U.

### The EMC Antenna 30

The EMC antenna 30 may be adjusted to a fixedly defined distance with respect to the system to be measured, which is located on the rotary plate 20. For example, the distance may amount to 1 meter. The EMC antenna may be configured movably. For example, the distance to the button of the measurement area may be adjusted (e.g., between 10 cm and 50 cm). Moreover, it may also be provided for adjusting the rotary angle about its vertical axis (e.g., about ±90°). A rotation about a horizontal axis (e.g. about ±90°) may also be provided such that the EMC antenna may be brought from a horizontal alignment into a vertical alignment.

Alternatively, an EMC camera may be arranged movably in the measurement area. If needed, it may be aligned renewably. In order to be able to not affect or interfere with the measurement during a measurement with an EMC antenna 30, the EMC camera may be pivoted away or may be retracted into the lower part U of the measurement cell.

### The Robot Arm 40

Preferably, the robot arm 40 is arranged adjacent to the rotary plate 20. By means of the robot arm, measurement devices, as near field probes and/or other sensors, may be advanced to the system to be inspected precisely with the cover 10 closed. The robot arm may be controlled from the outside by means of a mouse via a software program.

In addition to or alternatively to the near field probes and/or sensors, the robot arm 40 may also receive a thermal image camera, an EMC camera, or other optical and/or acoustical measuring sensors.

In order to not disturb the EMC antenna or the measuring process during an EMC measurement, it may be provided for the robot arm being configured pivotably or retractable into the lower part U of the measurement cell. Alternatively, the robot arm may be configured to be removable.

### The Thermal Image Camera

Magnetic fields at the system to be inspected may be made visible by means of the thermal image camera. It may be configured movably (movable or rotatable horizontally and/or vertically), for example, by means of a pneumatically or electro-motively driven system. The components of the pneumatically or electro-motively driven system, which may affect an EMC measurement, here, are arranged preferably outside of the measurement area, for example, in the lower area U. The control may be accomplished via a software program.

### The Cameras 50

With respect to the device shown here, cameras 50 are arranged at the corners (preferably, at the upper corners) of the measurement area, here, namely, a total of four cameras 50. However, there may also be provided more or less than four cameras. With these, the measurements may be monitored with the cover 10 closed. The cameras may be connected to a storing means, as a video recorder, in order to store or record the images provided by the cameras, and/or display them on monitors at the outside of the laboratory. The cameras are controlled from the outside via a corresponding control software. Also these cameras 50 may be re-arranged movably in the measurement area, in order to be able to adjust their position and/or alignment in the measurement area.

### The Measurement Devices 70

The measurement devices 70 are arranged in the lower area U of the box. Preferably, the measurement devices are arranged releasably in the lower area such that they may be removed or replaced, if needed. As measurement devices or further components in the lower area of the box, the following devices or components may be provided: analyzer, oscilloscope, power supply unit, T-network reproduction, drive device (as electro-motors) and/or pressurized air generators for the drive of the components (e.g., rotary plate 20, robot arm 40) in the measurement area, and/or video recorders.

Further, various terminals may be provided in the lower area U of the box 10. Hereby, the measurement cell and/or the individual devices may be switched on and off, and may be supplied with AC/DC and/or LAN and/or pressurized air. Here, moreover, a direct connection to the rotary plate terminals and the power sockets with the various terminals is possible with the cover 10 closed.

### The Fan

One or more fans may be arranged in the upper area O and/or in the lower area U in order to allow for cooling. The fans are not shown in the figures. In the upper area O, it is advantageous to provide special EMC filter fans, which offer a substantially better shielding effect and damping against electromagnetic fields, and thereby, higher EMC reliability.

### The Microphone

Further, a microphone not shown in the figures may be provided in the measurement area. The microphone may be located in the vicinity of the rotary plate 20. Thereby, the measurements may be monitored with the cover 10 closed. Sounds may be transmitted via a loudspeaker to the outside via a preamplifier.

### The Illumination

An illumination means may be provided in the interior of the measurement area, in order to obtain illumination, which is optimal for the cameras 50. According to a preferred embodiment of the invention, this illumination may be provided by one or more LEDs. The use of a so-called LED panel is preferable, which is arranged at the ceiling (and, if needed, at the sidewalls) of the measurement area. An area lighting is obtained by means of an LED panel, which at the same time minimizes shadowing.

### Power Sockets and Further Terminals

Further, power sockets and further terminals may be provided in the interior of the measurement area for power and signal transmission. Preferably, they are arranged in the bottom of the measurement area such that they preferably do not impair an EMC measurement. According to an embodiment of the invention, so-called floor power sockets may be used for this.

The following measurements may be made by means of the device according to the invention:
1. All types of wire-bound measurements may be carried out without additional effort.
2. All types of the radiated emission measurements may be carried out without additional effort.

When providing corresponding measurement devices, also an error analysis of the system to be inspected may be carried out by means of the device according to the invention, as an error analysis using the thermal image camera, or an error analysis by means of wire-bound measurements.

### REFERENCE NUMERALS

1 box (EMC measurement cell)
10 cover (slidable, foldable)
20 rotary plate
30 antenna
40 robot arm
50 cameras
55 thermal image camera
60 displays
70 measurement devices
M measurement chamber/measurement area
O upper area of the box
U lower area of the box

What is claimed is:

1. A device (1) for making EMC test measurements, wherein the device comprises a measurement cell configured as a mobile box, wherein
the box (1) comprises an opening at one side, which may be opened and closed again at least partially, wherein the opening is configured such that a system to be inspected can be introduced into the interior of the box through it,
the interior of the box is subdivided into two areas, preferably, into an upper area (O) and a lower area (U),
measurement devices (70) can be arranged in either one of the areas (U; device area), and the system to be inspected can be arranged in the respectively other area (O; measurement area),
the subdivision of the interior of the box into two areas (U; O) results from a plate, wherein the plate comprises an absorber layer and/or a damping layer and/or a shielding layer, in order to prevent disturbances of the system to be inspected by the measurement devices (70) and/or disturbances of the measurement devices (70) by the system to be inspected to a large extent.

2. The device of claim 1, wherein in the measurement area (O; M), at least one means selected from the group comprising a robot arm (40), a rotary plate (20), camera systems (50), an EMC antenna (30), sensors, a microphone, illumination, a thermal image camera, an EMC thermal image camera, an EMC fan, and combinations thereof, can be arranged

3. The device of claim 1, wherein the measurement devices (70) can be arranged releasably in the device area (U), in order to allow for a simple and quick exchange of the measurement devices.

4. The device of claim 2, wherein the components arranged in the measurement area (O; M) are arranged releasably in the measurement area, in order to allow for a simple and quick exchange of the components and an interference-free measurement.

5. The device of claim 1, wherein at least one display means (60) is provided at the outer wall of the box, preferably, a flat screen, which can be coupled to the components in the measurement area (O; M) and/or to the measurement devices (70) in the measurement area (U).

6. The device of claim 5, wherein the display means (60) is arranged releasably at the box, and/or wherein the display means is arranged pivotably at the box.

7. The device of claim 1, wherein the measurement devices (70) are selected from the group comprising at least an analyzer, and oscilloscope, a DC power supply unit, a T-network reproduction, a videorecorder, and combinations thereof.

8. The device of claim 2, wherein the robot arm (40) is configured and arranged relative to the rotary plate (20) such that at least a sensor and/or at least a measurement means can be moved relative to the rotary plate by means of it.

9. The device of claim 2, wherein the components (20; 30; 40; 50) arranged in the measurement area (O; M) are controllable from outside of the box, as by means of a joystick, a mouse, or any other input device.

10. The device of claim 2, wherein the EMC antenna (30) is configured so as to be alignable in the measurement area (O; M), wherein the alignment of the EMC antenna is accomplished from outside of the box.

11. The device of claim 2, wherein the camera system (50) comprises at least one, preferably two, particularly preferred, four cameras, wherein the cameras are arranged in the corner regions in the interior of the measurement area (O; M) stationary or movably.

12. The device of claim 2, wherein the camera system (50) comprises at least one thermal image camera, wherein the thermal image camera is arranged movably relative to the rotary plate (20) and the measurement area (O; M).

13. The device of claim 2, wherein the rotary plate (20) is controllable from the outside of the box, in particular, its rotation direction and its rotation speed.

14. The device of claim 1, wherein the sidewalls of the box are made from a metal, and particular, from aluminum.

15. The device of claim 1, wherein the box has a maximum dimension of 300×240×260, preferably, of 200×140×160, particularly preferred of 140×60×80 (L×W×H in cm).

16. The device of claim 1, wherein the walls (side walls and ceiling or upper wall) of the measurement area (O; M) comprise an absorber layer and/or a damping layer and/or a shielding layer, in order to shield the inner space of the measurement area from the outside and to prevent disturbances of a system to be inspected.

17. The device of claim 1, wherein the opening can be closed by means of flaps (10) or doors (10), wherein the flaps or doors comprise an absorber layer and/or a damping layer and/or a shielding layer.

18. The device of claim 1, wherein the absorber layer and/or the damping layer and/or the shielding layer of the plate are formed by a metal plate, onto which a layer of ferrite tile is applied.

19. The device of claim 16, wherein the absorber layer and/or the damping layer and/or the shielding layer of the walls comprise an EMC foil at the inner walls, onto which a polyurethane foam preferably effective in the frequency range between 20 MHz to 15 GHz is applied.

20. The device of claim 2, wherein the movably configured components arranged in the measurement area (O; M) are movable by means of drive systems, wherein the drive systems are arranged at least partially in the device area (U) or outside of the measurement area (O; M).
